(19) United States
(12) Patent Application Publication
(10) Pub. No.: US 2023/0402667 A1
(43) Pub. Date: Dec. 14, 2023

(54) SYSTEMS AND METHODS FOR PROCESSING AND MANAGING USED LITHIUM-ION BATTERIES

(71) Applicant: Higher Wire, Inc., Phoenix, AZ (US)

(72) Inventor: Trevor Warren, Tempe, AZ (US)

(21) Appl. No.: 18/334,369

(22) Filed: Jun. 13, 2023

Related U.S. Application Data
(60) Provisional application No. 63/351,806, filed on Jun. 13, 2022.

(51) Int. Cl. H01M 10/48; H01M 10/44; G01R 31/392; H01M 10/0525

(52) U.S. Cl. CPC H01M 10/48; H01M 10/44; G01R 31/392; H01M 10/0525

(57) ABSTRACT

A method for processing used lithium-ion batteries includes disassembling a used lithium-ion battery configured for a high-load application, inspecting cells of the used lithium-ion battery, charging the cells, and assessing a state-of-health of each of the cells by running a discharge test to determine an internal resistance and a capacity, comparing the internal resistance and the capacity with manufacturer specifications, and determining the state-of-health based on the comparison. The method also includes categorizing each of the cells into a reuse category, a repurpose category, or a recycle category based on the state-of-health of the cells and reusing the cells categorized in the reuse category in a battery configured for a high-load application, repurposing the cells categorized in the repurpose category into a battery configured for a low-load application, and recycling the cells categorized in the recycle category.

### RELATED APPLICATIONS

This application claims the benefit of U.S. provisional patent application 63/351,806, filed Jun. 13, 2022, titled “Systems and Methods for Processing and Managing Used Lithium-Ion Batteries,” the entirety of the disclosure of which is hereby incorporated herein by this reference.

### TECHNICAL FIELD

Aspects of this document relate generally to systems and methods for processing used lithium-ion batteries. Aspects of this document also relate generally to battery management systems and methods.

### BACKGROUND

Lithium-ion batteries are a renewable energy source that power electric vehicles, thus supporting a transition away from fossil fuels. Lithium-ion batteries also power consumer electronics and other goods (e.g., power tools, yard tools, etc.). Thus, the demand for lithium-ion batteries has grown over recent years and is expected to grow exponentially over the coming years.

Although lithium-ion batteries provide an environmental benefit over fossil fuels, the solution is not perfect. For example, due to a lack of infrastructure and knowledge, only a small percentage of lithium-ion batteries are recycled in the United States. Even when lithium-ion batteries are recycled, recycling can only recover about half of the critical materials (and at high cost). Recycling also requires energy and toxic chemicals. An additional problem with lithium-ion batteries is that, without a shift in consumption or manufacturing, the demand for lithium-ion batteries will exceed the supply.

### SUMMARY

Some embodiments provide a method for processing used lithium-ion batteries. In some embodiments, the method includes disassembling a used lithium-ion battery. In some embodiments, the used lithium-ion battery is configured for a high-load application. In some embodiments, the method includes inspecting cells of the used lithium-ion battery, charging the cells of the used lithium-ion battery, and assessing a state-of-health of each of the cells. In some embodiments, assessing the state-of health is done by running a discharge test to determine an internal resistance and a capacity of each of the cells, comparing the internal resistance and the capacity with manufacturer specifications for each of the cells, and determining the state-of-health based on the comparison. In some embodiments, the method includes categorizing each of the cells into one of a plurality of categories including a reuse category, a repurpose category, and a recycle category based on the state-of-health of each of the cells, and reusing the cells categorized in the reuse category in a battery configured for a high-load application, repurposing the cells categorized in the repurpose category into a battery configured for a low-load application, and recycling the cells categorized in the recycle category.

In some embodiments, the method also includes analyzing the battery configured for a high-load application having the cells categorized in the reuse category and the battery configured for a low-load application having the cells categorized in the repurpose category while in use to determine performance metrics. In some embodiments, the method also includes storing the performance metrics of the battery configured for a high-load application having the cells categorized in the reuse category and the battery configured for a low-load application having the cells categorized in the repurpose category in a database, and performing statistical analysis based on the stored performance metrics to identify state-of-health drivers. In some embodiments, the method also includes using the statistical analysis to improve future state-of-health determinations of cells of used lithium-ion batteries. In some embodiments, the battery configured for a high-load application having the cells categorized in the reuse category includes a combination of new cells and the cells categorized in the reuse category. In some embodiments, assessing the state-of-health of each of the cells also includes determining a temperature rise during the discharge test and comparing the temperature rise with a threshold. In some embodiments, the state-of-health is a grade. In some embodiments, the state-of-health is an estimate of life remaining for the cell.

In some embodiments, a method for processing used lithium-ion batteries includes disassembling a used lithium-ion battery, analyzing cells of the used lithium-ion battery during a discharge test, assigning grades to a plurality of factors for each of the analyzed cells based on the discharge test, determining a state-of-health for each of the analyzed cells based on the grades of each of the plurality of factors, categorizing each of the analyzed cells into one of a plurality of categories including a reuse category, a repurpose category, and a recycle category based on the state-of-health of each of the analyzed cells, and reusing the cells categorized in the reuse category in a battery configured for a high-load application, repurposing the cells categorized in the repurpose category into a battery configured for a low-load application, and recycling the cells categorized in the recycle category.

In some embodiments, the plurality of factors includes an internal resistance, a capacity, and a temperature rise. In some embodiments, a grade of at least one of the plurality of factors is based on a comparison with manufacturer specifications for each of the analyzed cells. In some embodiments, the method also includes charging cells of the used lithium-ion battery and evaluating a charge of each of the charged cells during a waiting period. In some embodiments, the charged cells are only analyzed if the charge exceeds a predetermined voltage throughout the waiting period. In some embodiments, the waiting period comprises at least one day.

In some embodiments, a method for processing used lithium-ion batteries includes individually assessing a state-of-health of cells of a used lithium-ion battery configured for a high-load application, categorizing each of the cells into one of a plurality of categories including a reuse category, a repurpose category, and a recycle category based on the state-of-health of each of the cells, and repurposing the cells categorized in the repurpose category into a battery configured for a low-load application.

In some embodiments, the method also includes reusing the cells categorized in the reuse category in a battery configured for a high-load application and recycling the cells categorized in the recycle category. In some embodiments, the state-of-health of each of the cells is based on a plurality of factors. In some embodiments, the plurality of factors includes an internal resistance of each of the cells and a capacity of each of the cells. In some embodiments, the battery configured for a low-load application includes a combination of new cells and cells categorized in the repurpose category. In some embodiments, individually assessing the state-of-health of the cells includes running a discharge test on each of the cells to determine a capacity and an internal resistance of each of the cells. In some embodiments, individually assessing the state-of-health of the cells includes, for each of the cells, comparing the capacity and the internal resistance of the cell with manufacturer specifications for the cell.

Some embodiments provide a battery management system. In some embodiments, a battery management system includes a first state-of-health monitoring device coupled to a first rebuilt or repurposed battery. In some embodiments, the first state-of-health monitoring device is configured to transmit internal resistance data and capacity data of individual cells of the first rebuilt or repurposed battery over a network. In some embodiments, the battery management system includes a second state-of-health monitoring device coupled to a second rebuilt or repurposed battery. In some embodiments, the second state-of-health monitoring device is configured to transmit internal resistance data and capacity data of individual cells of the second rebuilt or repurposed battery over the network. In some embodiments, the battery management system includes a server configured to receive over the network and store the internal resistance data and capacity data of the individual cells of the first rebuilt or repurposed battery and the internal resistance data and capacity data of the individual cells of the second rebuilt or repurposed battery. In some embodiments, the battery management system is configured to determine state-of-health of the individual cells of the first rebuilt or repurposed battery based on the internal resistance data and capacity data of the individual cells of the first rebuilt or repurposed battery and state-of-health of the individual cells of the second rebuilt or repurposed battery based on the internal resistance data and capacity data of the individual cells of the second rebuilt or repurposed battery. In some embodiments, the battery management system includes a user device configured to receive an alert over the network when at least one of the individual cells of the first rebuilt or repurposed battery or at least one of the individual cells of the second rebuilt or repurposed battery have a state-of-health that is lower than a threshold state-of-health.

In some embodiments, the threshold state-of-health is a state-of-health that predicts an end-of-life within three dozen cycles. In some embodiments, the first state-of-health monitoring device is an integral part of the first rebuilt or repurposed battery. In some embodiments, the first state-of-health monitoring device is coupled to the first rebuilt or repurposed battery with a wired connection. In some embodiments, the first state-of-health monitoring device is wirelessly coupled to the first rebuilt or repurposed battery.

The foregoing and other aspects, features, and advantages will be apparent from the DESCRIPTION and DRAWINGS, and from the CLAIMS.

### BRIEF DESCRIPTION OF THE DRAWINGS

Implementations will hereinafter be described in conjunction with the appended drawings.

FIG. 1 shows a schematic illustration of a method for processing used lithium-ion batteries according to some embodiments.

FIG. 2 shows a schematic illustration of a method for processing used lithium-ion batteries according to some embodiments.

FIG. 3 shows an analyzer for running a discharge test on a cell of a used lithium-ion battery according to some embodiments.

FIG. 4 shows a flowchart of analyzing a cell of a used lithium-ion battery according to some embodiments.

FIG. 5 shows a schematic illustration of a rebuilt lithium-ion battery according to some embodiments.

FIG. 6 shows a schematic illustration of a repurposed lithium-ion battery according to some embodiments.

FIG. 7 shows a schematic illustration of a battery management system according to some embodiments.

FIG. 8 shows a schematic illustration of a battery energy storage system according to some embodiments.

FIG. 9 shows a schematic diagram of devices that can be used to perform and/or implement any of the embodiments disclosed herein.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations.

### DETAILED DESCRIPTION

Detailed aspects and applications of the disclosure are described below in the following drawings and detailed description of the technology. Unless specifically noted, it is intended that the words and phrases in the specification and the claims be given their plain, ordinary, and accustomed meaning to those of ordinary skill in the applicable arts.

In the following description, and for the purposes of explanation, numerous specific details are set forth in order to provide a thorough understanding of the various aspects of the disclosure. It will be understood, however, by those skilled in the relevant arts, that embodiments of the technology disclosed herein may be practiced without these specific details. It should be noted that there are many different and alternative configurations, devices and technologies to which the disclosed technologies may be applied. The full scope of the technology disclosed herein is not limited to the examples that are described below.

The singular forms “a,” “an,” and “the” include plural referents unless the context clearly dictates otherwise. Thus, for example, reference to “a step” includes reference to one or more of such steps.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

Throughout the description and claims of this specification, the words “comprise” and “contain” and variations of the words, for example “comprising” and “comprises”, mean “including but not limited to”, and are not intended to (and do not) exclude other components.

As required, detailed embodiments of the present disclosure are included herein. It is to be understood that the disclosed embodiments are merely exemplary of the invention that may be embodied in various forms. Therefore, specific structural and functional details disclosed herein are not to be interpreted as limits, but merely as a basis for teaching one skilled in the art to employ the present invention. The specific examples below will enable the disclosure to be better understood. However, they are given merely by way of guidance and do not imply any limitation.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions.

More specifically, this disclosure, its aspects and embodiments, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

The present disclosure relates to systems and methods for processing used lithium-ion batteries. The present disclosure also relates to battery management systems and methods. Lithium-ion batteries are a renewable energy source that power electric vehicles, thus supporting a transition away from fossil fuels. Lithium-ion batteries also power consumer electronics and other goods (e.g., power tools, yard tools, etc.). Thus, the demand for lithium-ion batteries has grown over recent years and is expected to grow exponentially over the coming years.

Although lithium-ion batteries provide an environmental benefit over fossil fuels, the solution is not perfect. For example, due to a lack of infrastructure and knowledge, only a small percentage of lithium-ion batteries are recycled in the United States. Even when lithium-ion batteries are recycled, recycling can only recover about half of the critical materials (and at high cost). Recycling also requires energy and toxic chemicals. An additional problem with lithium-ion batteries is that, without a shift in consumption or manufacturing, the demand for lithium-ion batteries will exceed the supply.

Extending the useful life of lithium-ion batteries would help with recycling concerns and supply concerns. According to some embodiments disclosed herein, used lithium-ion batteries can be disassembled and the cells evaluated to determine their state-of-health. The state-of-health is an indication of the remaining life of the battery. The state-of-health may be represented as a number of cycles remaining for the battery or as a percentage of life remaining. In some embodiments, the state-of-health evaluation is done cell-by-cell, rather than to an entire battery at once. Evaluating each cell individually facilitates comparison to the original manufacturer specifications for each individual cell, thus providing a more accurate depiction of the state-of-health. In some embodiments, the state-of-health evaluation looks at multiple factors and provides a grade or score for each factor. The overall state-of-health is based on the grade or scores of the individual factors. Based on the state-of-health evaluation, the cells can be reused in a battery (i.e., a rebuilt battery) for the same types of applications that the original battery was used for (e.g., high-load applications or low-load applications), repurposed in a battery for low-load applications (i.e., a repurposed battery), or recycled as explained below.

When the state-of-health of the cells meet certain criteria (e.g., receives a passing grade for a high-load discharge test), a used lithium-ion battery can be refurbished or rebuilt for use in the original intended application (e.g., electric scooters, electric golf carts, renewable energy storage, power tools, etc.). For example, those cells that meet the criteria may be reused in a new battery pack (i.e., a rebuilt battery), which may include only reused cells or a combination of reused cells and new cells. In some embodiments, the original intended application is a high-load application. In some embodiments, the original intended application is a low-load application.

When the state-of-health of the cells originally intended for a high-load application do not meet the criteria for a high-load application but meet the criteria for a low-load application (e.g., receives a passing grade for a low-load discharge test), the cells can be repurposed into a battery pack for low-load applications, such as stationary and portable energy storage. For example, a second-life battery energy storage system can be manufactured from used cells that are unfit for high-load applications.

When the state-of-health of the cells do not meet the criteria for a high-load application or a low-load application, then those cells have reached end-of-life. Those cells that have reached end-of-life may be recycled.

By processing used lithium-ion batteries in this manner, useful life of the battery is extended, thus bringing down overall costs. Moreover, a circular process flow is created for those cells that have not reached end-of-life. This circular process flow requires less energy than recycling and does not generate chemical waste.

In some embodiments, a battery management system is provided, which may include a state-of-health monitoring device for each battery being managed, a network, a server, and a user device. The battery management system may facilitate remotely monitoring each repurposed and/or rebuilt battery to alleviate the costs of manual monitoring. The battery management system may continuously evaluate the state-of-health of a repurposed and/or rebuilt battery, which may be made up of multiple groups of cells. For example, the battery management system may monitor either each group of cells or each individual cell while the battery is in service to determine, in advance, when a particular group or particular cell is expected to reach its end-of-life. When a group of cells or an individual cell is approaching its end-of-life, an alert can be provided over the network to a user device allowing for replacement of the group of cells or the individual cell, thus minimizing interruption of power provided by the repurposed battery.

In some embodiments, the batteries may be battery energy storage systems. The battery energy storage systems may comprise a plurality of battery cells, which may be reused cells, repurposed cells, new cells, or any combination of the foregoing cells. In some embodiments, a battery energy storage system comprises a plurality of high-gain DC-DC converters, with each converter corresponding to one of the battery cells. For example, each DC-DC converter may be coupled with one of the battery cells. The battery cells may be connected in parallel on an output (i.e., high voltage) side of the converters. By implementing high-gain DC-DC converters at the cell level and connecting the battery cells in parallel (rather than the conventional approach of connecting the batteries in series and using a single DC-DC converter), the battery energy storage system is able to maintain a stable voltage with a small loss in capacity in the event of individual cell failure, which reduces field failures and maximizes the system's productive life. In contrast, failure of a single battery cell in the conventional approach may cause the DC-DC link to collapse, resulting in a compromise of the power flow and poor structural modularity.

Moreover, in the conventional approach, battery energy storage systems (particularly those using reused or repurposed cells) are carefully assembled so that they use cells that are deemed to be close in state-of-health, capacity and internal resistance, and other factors, as well as being the same make and model, chemistry, and often from the same lot to ensure safety and reliability. This careful assembly demands time and resources, thus driving up costs. The cell-level DC-DC converter described herein will reduce the need for careful assembly because the criticality of each battery cell is reduced through the parallel configuration.

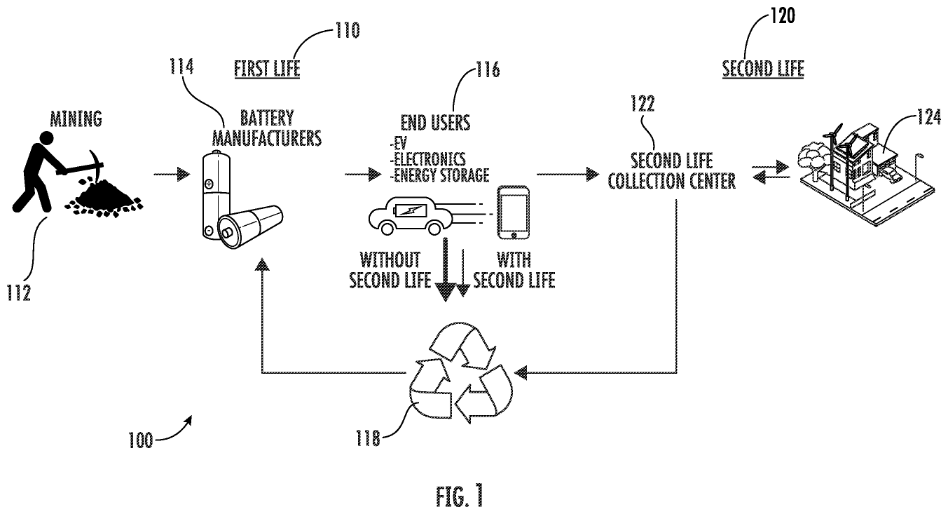

A schematic illustrating the general lifecycle 100 of lithium-ion batteries according to some embodiments is shown in FIG. 1. Conventionally, a battery only has one life (labeled in FIG. 1 as First Life 110 on the left-hand side). The present disclosure provides opportunities for Second Life 120 of the battery (labeled in FIG. 1 on the right-hand side). Although the schematic shows a representative Second Life 120, the battery cells may go through more than two uses. For example, battery cells may be reused one or more times in high-load applications. In addition, battery cells may be repurposed for low-load applications after one or multiple uses in high-load applications. Similarly, battery cells may be reused one or more times in low-load applications (whether their “First Life” 110 was for a high-load application or a low-load application).

At the beginning of the lithium-ion battery lifecycle, mining operations 112 retrieve materials used to create lithium-ion batteries, which are provided to battery manufacturers 114 to create new lithium-ion batteries. These batteries may be intended for original applications that are high-load applications, such as electric vehicles (e.g., scooters, golf carts, cars, etc.), consumer electronics (e.g., power tools), or energy storage. A high-load application is an application that requires a C-rate (the amperage rate of the battery compared to the maximum capacity of the battery) of 10 C or higher. In some embodiments, the batteries may be intended for original applications that are low-load applications (e.g., renewable energy storage, telecommunications, etc.). A low-load application is an application that can use batteries having a C-rate of less than 10 C.

The lithium-ion batteries may be installed in various devices, which may be distributed to an end user 116 (e.g., by sale of the device). After the user 116 is finished with the device (e.g., an electric vehicle, consumer electronics), the user 116 may get rid of the device with the battery inside (e.g., by taking it to a collection center for electronic devices). Alternatively, in some instances, the battery may be removed from the device (e.g., based on the amount of usage of a battery on an electric vehicle) and discarded to replace it with a new one. Conventionally, this was the end of the battery life for either of these scenarios. The battery would have been recycled without any second life 120 (regardless of its actual condition) as represented by the downward arrow and the recycle sign 118 at the bottom right of the First Life 110 representation. The materials recovered from the recycling process would have been returned to battery manufacturers 114 to make new lithium-ion batteries. However, as discussed above, only a small percentage of materials are recovered and this is done at high cost and using toxic materials.

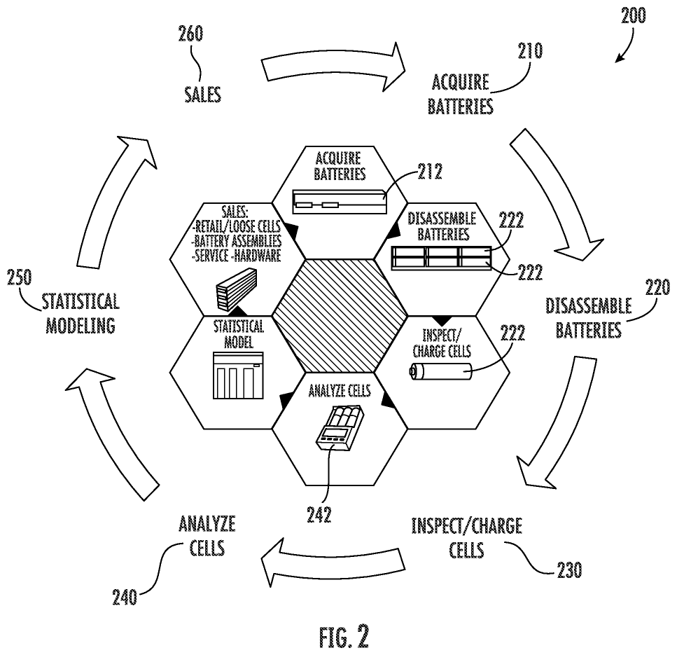

Thus, according to some embodiments, used lithium-ion batteries (either as part of a device or as a stand-alone battery removed from a device) may be provided to a unique Second Life collection center 122 (e.g., any business that reuses or repurposes lithium-ion battery cells) for analysis, which will be described in more detail below (see FIGS. 2-4). Based on this analysis, cells of the used lithium-ion batteries that meet certain criteria may be reused for originally intended applications in a rebuilt battery, while cells of the used lithium-ion batteries that meet lower criteria may be repurposed for another application (e.g., from a high-load application to a low-load application) in a repurposed battery. The reuse and repurpose options are represented by the right side of the “Second Life” 120 portion of the schematic in FIG. 1, which schematically shows potential uses 124 for the rebuilt or repurposed batteries. Because this process can be repeated multiple times, two arrows are included (one in each direction) between the Second Life collection center 122 and the schematic of potential uses 124. Thus, after a rebuilt or repurposed battery has been used, it may be returned to the Second Life collection center 122 for further analysis of the battery cells and additional reuse or repurposing (depending on the analysis). The schematic of end users 116 shows additional options of potential uses for a rebuilt or repurposed battery (including electric vehicles, electronics, and energy storage).

As a third option, when the analysis shows that cells of the used lithium-ion batteries do not meet any of the criteria for reuse or repurposing, the cells have reached their end-of-life and may be sent to a recycling center 118, as illustrated by the arrow from the Second Life collection center 122 to the recycling symbol 118. In some embodiments, an end user 116 may directly recycle a rebuilt or repurposed battery without returning the battery to a second life collection center 122, as illustrated by the arrow from end user 116 to the recycling symbol 118 that is labeled “With Second Life.”

FIG. 2 shows the operational process flow 200 of the Second Life collection center 122 according to some embodiments. The operational process flow 200 may be a method for processing used lithium-ion batteries 212. In some embodiments, the first step of the operational process flow 200 is to acquire used batteries 212, as shown at operation 210 at the top of the operational process flow 200 in FIG. 2. In some embodiments, the Second Life collection center 122 may acquire used batteries 212 through partnerships with municipal recycling centers 118, other recycling companies 118, or electric vehicle manufacturers. Other methods of acquiring used batteries may also be implemented. For example, consumers may directly provide used electronic devices or stand-alone lithium-ion batteries 212 to the Second Life collection center 122. The acquired batteries 212 may be batteries intended for high-load applications, batteries intended for low-load applications, or both.

In some embodiments, the Second Life collection center 122 may disassemble the batteries that have been acquired at operation 220. By disassembling the batteries, the Second Life collection center 122 may isolate individual cells 222 for individual analysis.

In some embodiments, the next step is to inspect and charge the cells at operation 230. Inspecting the cells 222 may include visual inspection to look for any rust, damage to the cells 222 (e.g., physical damage to the casing), corrosion, or other issues with the cells 222. When the visual inspection identifies damage or other issues, the cells 222 may be marked for recycling 118. Alternatively, if the damage or other issues can be addressed, the Second Life collection center 122 may do so before charging the cell 222.

In some embodiments, after inspecting the cells 222, the voltage of the battery cells is checked as part of operation 230. If needed, the cell is charged in preparation for additional analysis at operation 240 including determining whether the cell 222 can hold a charge and performing a discharge test.

First, the Second Life collection center 122 determines whether the battery cell 222 is able to hold a charge. In some embodiments, there may be a waiting period after charging the cell 222. At the end of this waiting period, the battery cell 222 is checked to see if it retained the charge. In some embodiments, the charge of the battery cell 222 is evaluated throughout the waiting period. The waiting period may be at least one week. For example, the waiting period may be one week, two weeks, or one month. Other waiting periods may also be used, including one day, three days, five days, etc. If the battery cell 222 maintains a charge above a certain voltage through the waiting period, then the battery cell analysis 240 proceeds to the discharge test. In some embodiments, the voltage is 4 volts. For example, the battery cell 222 can be evaluated to see if it holds a charge of at least 4 volts for at least a one-week period. Other voltages or waiting periods may also be used.

In some embodiments, after determining whether the battery cell 222 can hold a charge, a cell is analyzed at operation 240 (represented at the bottom of FIG. 2) through a discharge test to determine the state-of-health of the battery cell 222. The state-of-health indicates how much remaining life the battery cell 222 has. During the discharge test, several factors are evaluated. These factors may include, but are not limited to, internal resistance, capacity, and temperature rise during the discharge profile. Each factor may receive a grade or a score. Based on the grade or score of each individual factor, an overall state-of-health is determined for the battery cell 222.

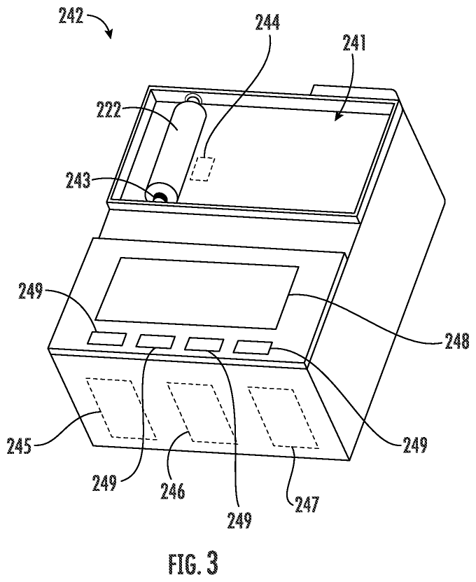

In some embodiments, the discharge test is performed by connecting the battery cell to an analyzer 242. An analyzer 242 according to some embodiments is shown, for example, in FIG. 3. Other configurations of an analyzer are also possible. In some embodiments, analyzer 242 comprises cell receptacle or section 241 configured to receive one or more battery cells 222 for analysis. In some embodiments, analyzer 242 may receive two to ten battery cells 222 at a time. For example, analyzer 242 may receive four battery cells 222. In some embodiments, analyzer 242 does not actually receive battery cells 222 but is instead electrically coupled to a battery cell in a different manner. The analyzer 242 may use a spring-loaded mechanism 243 to maintain contact with the battery cell 222. Analyzer 242 may have a plurality of spring-loaded mechanisms 243 (e.g., one for each battery cell 222). In some embodiments, the analyzer 242 includes a temperature sensor 244 (shown schematically in FIG. 3), such as a thermistor, to monitor the temperature of the battery cell 222. Analyzer 242 may have a plurality of temperature sensors 244 (e.g., one for each battery cell 222).

The analyzer 242 may also include a module 245 for charging the battery cell (as discussed above with respect to determining whether the battery can retain a charge). For example, the analyzer 242 may include a TP4056 board (or some other charger 245) for charging the battery cell 222. In some embodiments, analyzer 242 may include a module 246 for discharging battery cell 222. For example, the analyzer 242 may be configured to use pulse-width modulation (PWM) to apply a load for discharge and DC internal resistance testing. In some embodiments, the analyzer 242 may also include a transceiver 247 (such as a Wi-Fi module) for remotely monitoring a battery (as discussed below) and connection to a database (e.g., a Structured Query Language (SQL) database). Analyzer 242 may also use other connections, such as a wired connection, to input data from the analysis 240 of battery cell 222.

In some embodiments, analyzer 242 comprises a display screen 248 to display results of the discharge test or other information. In some embodiments, analyzer 242 comprises one or more buttons 249 to allow a user to control operation of analyzer 242.

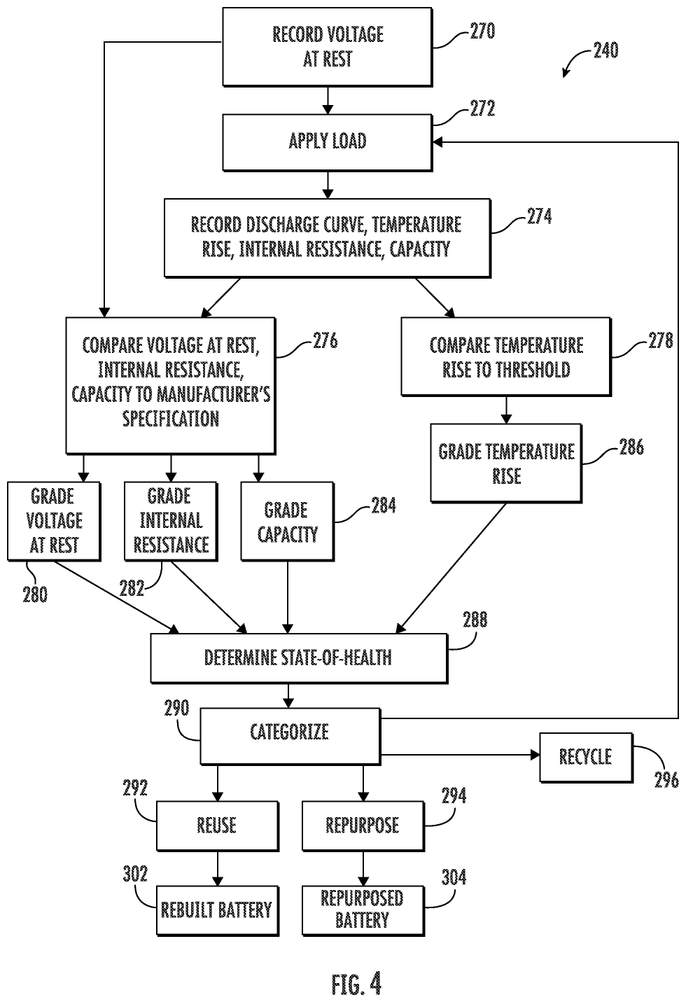

Additional details of analysis 240 of a cell 222 according to some embodiments is shown, for example, in FIG. 4. Variations from analysis 240 shown in FIG. 4 are also possible. For example, in some embodiments, analysis 240 may include additional or fewer operations and the order of operations may be different. As another example, additional, fewer, or different factors than those discussed with respect to FIG. 4 may be used to analyze cells 222.

In some embodiments, at operation 270, the analyzer 242 records the voltage-at-rest of the battery cell 222, after which a load is applied to the battery cell 222 at operation 272. By applying a load and recording data discussed below, analyzer 242 is performing the discharge test. The applied load may be such that the battery cell 222 is discharged at 0.2 C (e.g., 500 milliamps for a 2.5 Ah cell). In some embodiments, at operation 274, the analyzer 242 then records the discharge curve, the temperature rise, the internal resistance, and the capacity of the battery cell 222 as the battery cell 222 is discharged. This data may be recorded into a database for later analysis.

In some embodiments, at operation 278 the temperature rise through the discharge profile is compared to one or more thresholds to determine the grade or score for temperature rise at operation 286. For example, if the temperature rise is greater than 50 degrees Celsius, the grade for temperature rise may be a failing grade (a grade of F). Any temperature rise of 50 degrees Celsius or less may be a passing grade. Alternatively, there may be other thresholds (e.g., 10, 20, or 40 degrees Celsius) to distinguish between A, B, C, or D grades.

Grades for other factors may be determined by comparison to the specifications from the original manufacturer for that particular cell 222's make and model. For example, at operation 276, the voltage at rest, internal resistance, and capacity of cell 222 may be compared with the manufacturer's specifications for cell 222. At operation 280, the grade for voltage at rest is determined. At operation 282, the grade for internal resistance is determined. At operation 284, the grade for capacity is determined. The specifications for a number of different makes and models of battery cells 222 may be stored in a database to facilitate comparison. In some embodiments, after the discharge test is complete, the make and model of the battery cell 222 are entered (e.g., through a computer interface). In some embodiments, grades for various factors (e.g., internal resistance, capacity, voltage at rest, etc.) are automatically outputted after the make and model of the battery cell 222 are entered. For example, a computer may compare the data from the discharge test to the manufacturer specifications for that make and model of battery cell 222 that are stored in the database. The grades may be based on the ratio of the measured parameters to the specification parameters. For example, if the measured internal resistance is 100% or lower of the specification internal resistance, the internal resistance factor may have a grade of A. Similarly, 101-200% may be a B grade, 201-300% may be a C grade, 301-500% may be a D grade, and higher than 500% may be an F grade. Other thresholds may alternatively be used, such as smaller or bigger ranges for one or more of grades A-F (e.g., D grade may be 301-400% and above 400% may be an F grade). Similar comparisons and grades may be used for the other factors, such as capacity of the battery cell 222. Because the capacity may decrease over the life of the battery cell 222, the percentages may be reversed (e.g., 90-100% for A grade, 80-89% for B grade, 70-79% for C grade, 60-69% for D grade, below 60% for F grade).

Based on the grades of each factor, an overall state-of-health may be determined at operation 288. In some embodiments, the overall state-of-health is equal to the lowest grade of any individual factor. For example, if the lowest grade of an individual factor is C, then the overall state-of-health is a C grade. In some embodiments, the overall state-of-health is determined by averaging the grades of each individual factor. In some embodiments, the overall state-of-health is determined by weighting the grades of each individual factor (i.e., so that one factor may be given greater weight than another factor). In some embodiments, the overall state-of-health is determined by a combination of the foregoing options. For example, the overall state-of-health may be determined by averaging (or assigning weights) unless one of the individual factor's grade is a D or an F grade, at which point the overall state-of-health is assigned a corresponding D or F grade.

For cells 222 originally intended for high-load applications, the same discharge test may be done but at a higher load at operation 272. For example, the applied load may be such that the battery cell 222 is discharged at 1 C (e.g., 2.5 amps for a 2.5 Ah cell) compared to 0.2 C for a low-load test. Based on the grades, each individual cell 222 may be categorized at operation 290 into a reuse category 292, a repurpose category 294, or a recycle category 296. If the cells 222 are graded at a certain threshold or higher using the higher load discharge test (e.g., a C grade or higher), then the cells 222 may be categorized in the reuse category 292. If the cells 222 do not meet the threshold at the higher load discharge test, they may be tested at the lower load discharge test, as shown by the arrow from operation 290 returning up to operation 272. Those cells 222 graded at a certain threshold or higher using the lower load discharge test (e.g., a C grade or higher) may be categorized in the repurpose category 294. Those cells 222 that do not meet the threshold at the lower load discharge test may be categorized in the recycle category 296.

The cells 222 categorized in the reuse category 292 may be used to rebuild a battery for the same type of application as the originally intended application (e.g., a high-load application or a low-load application), which is considered a rebuilt battery 302. The cells 222 categorized in the repurpose category 294 may be repurposed into a battery configured for a low-load application, which is considered a repurposed battery 304. The cells 222 categorized in the recycle category 296 may be recycled 118 (see FIG. 1).

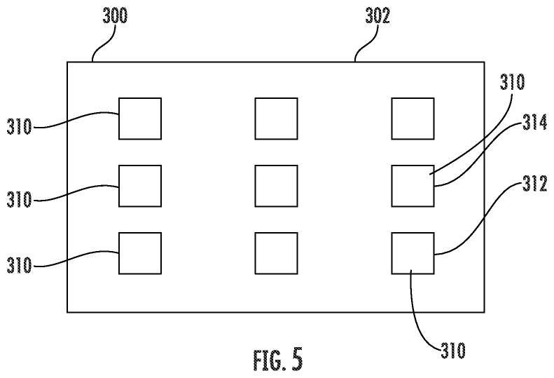

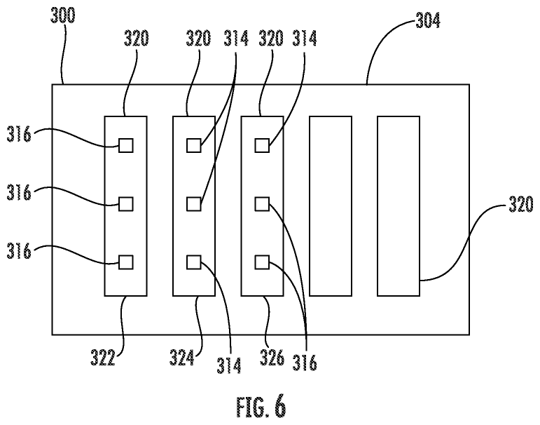

Schematic illustrations of batteries 300 (comprising individual cells 310, which may be configured as groups 320 of cells) resulting from the process discussed above are shown in FIGS. 5 and 6. For example, battery 300 may be a rebuilt battery 302, as shown, for example, in FIG. 5. In some embodiments, a rebuilt battery 302 only includes cells 312 from the reuse category 292 (i.e., no new cells 314 are used). In some embodiments, a rebuilt battery 302 includes a combination of new cells 314 and the cells 312 categorized in the reuse category 292 (as shown in FIG. 5). Although FIG. 5 shows nine cells 310, any number of cells 310 may be used for the rebuilt battery 302. For example, a rebuilt battery 302 may include one or more cells 310 (which may be all reused cells 312 or a combination of reused cells 312 or new cells 314). In some embodiments, a rebuilt battery 302 includes one hundred cells 310. The cells 310 may be provided as groups of cells (for example, the way groups 320 of cells are schematically represented in FIG. 6). For example, a rebuilt battery 302 may include five groups of twenty cells 310 each. Other numbers of groups 320 or number of cells 310 per group 320 may be used.

Battery 300 may be a repurposed battery 304, as shown, for example, in FIG. 6. In some embodiments, a repurposed battery 304 only includes cells 310 from the repurpose category 294 (i.e., no new cells 314 are used). In some embodiments, a repurposed battery 304 includes a combination of new cells 314 and the cells 316 categorized in the repurpose category 294. A repurposed battery 304 may include one or more cells 310 (which may be all repurposed cells 316 or a combination of repurposed cells 316 and new cells 314). In some embodiments, a repurposed battery 304 includes one hundred cells 310. The cells 310 may be provided as groups 320 of cells 310, as shown in FIG. 6. For example, a repurposed battery 304 may include five groups 320 of twenty cells 310 each. Although FIG. 6 shows five groups 320 of cells 310, any number of groups 320 may be used for the repurposed battery 304. Other numbers of cells 310 per group 320 may be used. In some embodiments, a group 320 may include only repurposed cells 316, such as group 322. In some embodiments, a group 320 may include only new cells 314, such as group 324. In some embodiments, a group 320 may include a combination of repurposed cells 316 and new cells 314, such as group 326.

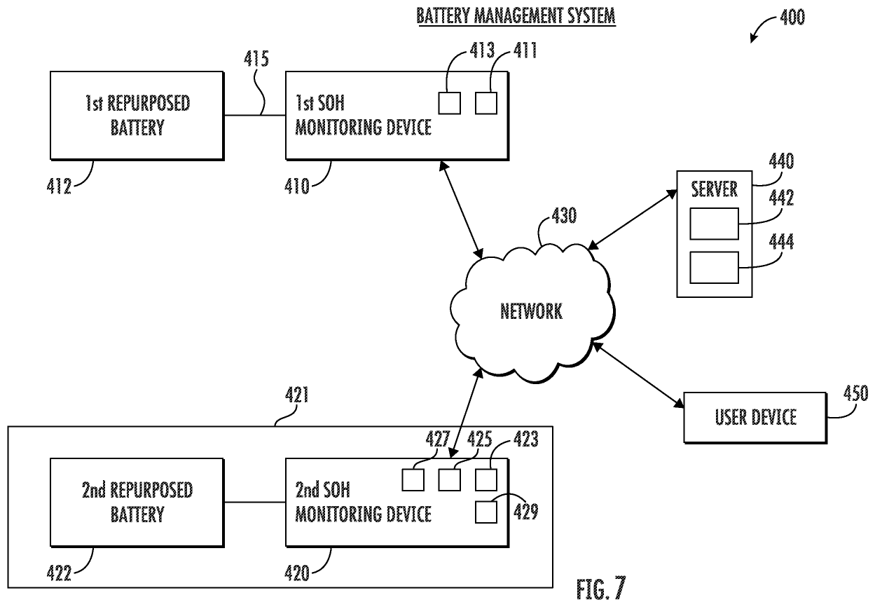

In some embodiments, rebuilt batteries 302 and/or repurposed batteries 304 may be analyzed while in use to determine key performance metrics, determine state-of-health of the rebuilt batteries and/or repurposed batteries, and identify state-of-health drivers. This analysis may be done using the battery management system discussed below (see FIG. 7). Returning to FIG. 2, this analysis is represented at operation 250 of statistical modeling. Using statistical analysis to identify state-of-health drivers for rebuilt batteries 302 and repurposed batteries 304 may improve the state-of-health determination of used battery cells 222 discussed above. For example, the actual battery life of the rebuilt batteries 302 and repurposed batteries 304 may be factored into future grade determinations (e.g., by giving certain factors more weight when that factor has been identified as a driver of state-of-health). As another example, in some embodiments, the statistical analysis may facilitate replacing a grade for each cell 222 (as discussed above) with an estimate of life remaining for each battery cell (e.g., a number of cycles remaining, or an amount of time remaining, before end-of-life, or a percentage of life remaining). The estimate of life remaining may be tied to particular applications (e.g., how long the battery cell will last if used for a particular application). Thus, the method may improve over time by using statistical analysis and incorporating feedback from previously rebuilt batteries 302 and repurposed batteries 304.

The final step in the operational process flow 200 is sales at operation 260. The sales may include sales of the rebuilt batteries 302, repurposed batteries 304, and cells 222 for recycling (e.g., materials from recycled cells being sold to battery manufacturers 114). The rebuilt batteries 302 and repurposed batteries 304 may include, for example, a mobility pack for an electric vehicle and batteries for off-grid renewable energy, solar light systems and generators, park lights, bus stops, telecommunications systems, and other high- or low-load applications.

In some embodiments, a battery management system is provided to manage rebuilt and/or repurposed batteries. A schematic of an example battery management system 400 is shown in FIG. 7. The battery management system 400 may include a first state-of-health monitoring device 410 coupled with a first repurposed (or rebuilt) battery 412, a second state-of-health monitoring device 420 coupled with a second repurposed (or rebuilt) battery 422, a network 430, a server 440, and a user device 450. The batteries 412, 422 may have the features of batteries 300 (e.g., battery 302, battery 304) discussed above. The monitoring devices 410, 420, the server 440, and the user device 450 may each be communicatively coupled to a network 430 to facilitate communication between the different components. Thus, the battery management system 400 may facilitate remotely monitoring each repurposed (or rebuilt) battery 412, 422 to alleviate the costs of manual monitoring.

Additional features of monitoring devices 410, 420 are discussed below. Although FIG. 7 shows first monitoring device 410 as having some features and second monitoring device 420 as having other features, this is just for brevity. It should be understood that a single monitoring device (410 or 420) may have all or any subset of the features discussed and shown with respect to any monitoring device 410, 420.

In some embodiments, monitoring device 410 includes a current-measuring device 411. For example, the current-measuring device 411 may be an internal or an external shunt. In some embodiments, monitoring device 410 includes one or more field-effect transistors 413, which are used to control the flow of current and to balance the cell-string voltages of battery 412. Monitoring devices 410, 420 may be coupled to the batteries 412, 422 in a variety of ways. For example, monitoring device 410 may be a separate device that has a wired connection with the battery 412. The battery management system 400 may include leads 415 that connect a monitoring device 410 to the positive and negative ends of each cell-string, which is a collection of cells wired in parallel, in the monitored battery 412 to monitor voltage. The monitoring device 420 may be an integral part of the battery 422 (e.g., within a single housing 421). In some embodiments, the monitoring device 410, 420 may be wirelessly coupled with the battery 412, 422. In some embodiments, the monitoring device 410, 420 may transmit data wirelessly to a central processing unit (such as server 440) for further analysis. The monitoring device 410, 420 may include some or all of the features and capabilities discussed above with respect to the analyzer 242.

The monitoring device 410, 420 continuously collects data from the battery 412, 422, and the data may be provided to other components of the management system 400 to continuously evaluate the state-of-health of a repurposed or rebuilt battery 412, 422. In some embodiments, the monitoring device 410, 420 is configured to collect data from each cell 310 of the repurposed or rebuilt battery 412, 422 individually. Thus, the monitoring may provide cell-level information. The data collected by the state-of-health monitoring devices 410, 420 may be the same data that is collected during the state-of-health evaluation of cells 222 from used batteries 212 discussed above (e.g., internal resistance, capacity, temperature rise, etc.). In some embodiments, the state-of-health monitoring devices 410, 420 are configured to use Kalmann filtering, Coulomb counting, and/or neural networks and machine learning to monitor the remaining life and state-of-health of a fielded battery 412, 422 (e.g., a repurposed or rebuilt battery). The data obtained from these devices 410, 420 may be transferred to a central database 442 (e.g., at the server 440) for analysis. The database 442 may be the same database referenced above in the discussion of analyzing cells 222. In some embodiments, the monitoring devices 410, 420 include a microcontroller unit 423, a digital signal processor 425, and/or a field-programmable gate array 427.

In some embodiments, the monitoring device 420 comprises a transceiver 429 to facilitate communication with the network 430. In some embodiments, the network 430 is a wide area network (e.g., the internet). Other types of networks 430 may also be used. For example, a local area network 430 may be used to monitor a plurality of batteries 412, 422 at a single location.

The monitoring device 410, 420 may periodically send the collected data over the network 430 to be stored in the server 440. The server 440 may include a processor 444 that determines the state-of-health of the cells 310 in batteries 412, 422. In some embodiments, the monitoring device 410, 420 itself determines the state-of-health, which is sent (together with the collected data) over the network 430. In some embodiments, the management system 400 evaluates state-of-health of a group 320 of cells 310 (see FIGS. 5-6), with the goal of keeping the internal resistance and the capacity of each group 320 in a battery 412, 422 as consistent with each other as possible. For example, the battery management system 400 may monitor each group 320 of cells 310 while the battery 412, 422 is in service to determine, in advance, when a particular group 320 is expected to reach its end-of-life. In some embodiments, the management system 400 evaluates state-of-health of each cell 310, with the goal of keeping the internal resistance and the capacity of each cell 310 in a group 320 as consistent with each other as possible.

When a group 320 of cells 310 is approaching its end-of-life (or an individual cell 310), an alert can be provided over the network 430 to a user device 450 allowing for replacement of the group 320 of cells 310 (or an individual cell 310), thus minimizing interruption of power provided by the repurposed or rebuilt battery 412, 422. For example, an alert may be provided to the user device 450 (which may be a computer, a mobile device, a tablet, or other electronic device) when a group 320 of cells 310 (or an individual cell 310) is predicted to only have a few dozen cycles remaining (e.g., 3 dozen cycles remaining).

The rebuilt or repurposed battery 412, 422 may be configured to be field-repairable such that a technician can easily replace a cell 310, or a group 320 of cells 310 at the battery 412, 422's location during use. For example, the cells 310 may be simply dropped into place in the battery 412, 422 rather than requiring welding. In response to an alert, a technician may bring a replacement cell 310 or group 320 of cells 310, remove the cell 310 or group 320 of cells 310 that are at end-of-life, and drop in the replacement cell 310 or group 320 of cells 310.

Although FIG. 7 illustrates first and second repurposed batteries 412, 422, the system 400 may be used to manage only repurposed batteries (e.g., for low-load applications), only rebuilt batteries (e.g., for high-load applications or low-load applications), or a combination of repurposed and rebuilt batteries. Only two batteries 412, 422 are shown in FIG. 7, but the battery management system 400 may manage many more batteries than what is shown. For example, hundreds or thousands of batteries may be managed by a battery management system 400. Similarly, multiple networks 430, multiple servers 440, and/or multiple user devices 450 may be used as part of a battery management system 400.

The data and key performance metrics stored in the server 440 of the battery management system 400 may be used to improve the state-of-health determination for cells 310 of used batteries 212, as discussed above. In particular, statistical analysis may be used to determine state-of-health drivers that improve estimates of remaining life for each battery cell 222 depending on the intended applications.

In some embodiments, a battery energy storage system is provided. The batteries 412, 422 (whether rebuilt or repurposed) may provide the battery energy storage system discussed herein (and thus have the features discussed below). Moreover, the features of the battery energy storage system discussed herein may also be implemented with new cells 314. Thus, the battery energy storage systems may comprise a plurality of battery cells 310, which may be reused cells 312, repurposed cells 316, new cells 314, or any combination of the foregoing cells 310.

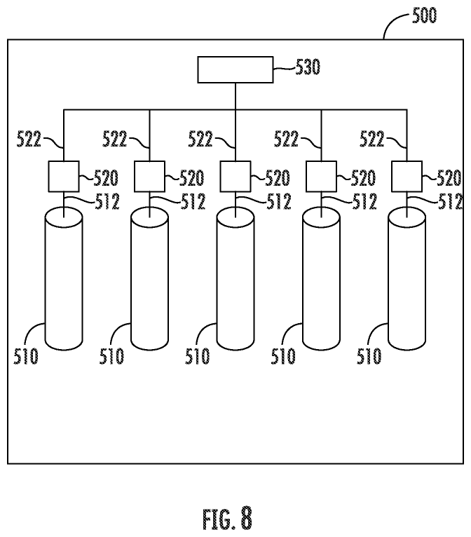

An example battery energy storage system 500 is shown, for example, in FIG. 8. In some embodiments, battery energy storage system 500 is a grid-integrated or grid-tied energy storage system. Battery energy storage system 500 comprises a plurality of battery cells 510 (which may be reused cells 312, repurposed cells 316, and/or new cells 314). In some embodiments, battery energy storage system 500 comprises a plurality of high-gain DC-DC converters 520, with each converter 520 corresponding to one of the battery cells 510. For example, each DC-DC converter 520 may be coupled with one of the battery cells 510. In some embodiments, DC-DC converters 520 convert the low voltage output from battery cells 510 to a high voltage output. In some embodiments, battery cells 510 have an output voltage 512 between one volt and five volts, which may be referred to as cell voltage 512. For example, the cell voltage 512 may be between 2.5 volts and 4 volts. Other voltages (e.g., more than five volts or less than one volt) may also be used as cell voltage 512 from battery cells 510. Cell voltage 512 provides an input voltage for DC-DC converters 520.

In some embodiments, DC-DC converters 520 have an output voltage 522 that is greater than 300 volts, which may be referred to as DC bus voltage 522. For example, DC-DC converters 520 may provide a DC bus voltage 522 of 360 volts. DC bus voltage 522 is available at DC bus (or DC link) 530, which may be used as a power source for a variety of applications. In some embodiments DC bus 530 may supply power to an inverter (e.g., to convert DC voltage into AC voltage). In some embodiments, the converter circuitry comprises CLLC with half-bridge on DC bus 530. In some embodiments, the converter circuitry comprises LLC-variant circuit topology with full-bridge on the cell side and half-bridge on the DC link side.

Thus, in some embodiments, DC-DC converters 520 provide a well-regulated 360-volt DC link 530 from 2.5-volt to 4-volt cell voltage 512. DC-DC converters 520 may provide an ultra-high gain conversion (e.g., from cell voltage 512 to DC bus voltage 522). In some embodiments, the DC link 530 is provided at 2 kW rated load. In some embodiments, the battery energy storage system 500 (and its DC-DC converters 520 systems) allow bidirectional power flow. This would facilitate charging of cells 510 from, for example, solar photovoltaic cells or any other energy source ports.

In some embodiments, DC-DC converters 520 comprise wide bandgap semiconductors. For example, the wide bandgap semiconductors of the DC-DC converters 520 may be made of gallium nitride. The wide bandgap semiconductors may provide a high-frequency efficient power conversion system with reduced passive component footprints. In some embodiments, the DC-DC converters 520 exhibit a power density of 5 Watts per cubic inch. In some embodiments, the DC-DC converters 520 have dimensions of 2 inches by 5 inches by 2 inches. In some embodiments, the DC-DC converters 520 are up to 98% efficient at rated load and nominal state-of-charge conditions. Wide bandgap semiconductor-based power electronics in a high-gain DC-DC power converter system may result in high converter- and system-level efficiency, higher power density, improved reliability and greater margins of safety. Thus, an easily reconfigurable and scalable grid-integrated energy storage system is provided.

In some embodiments, the battery cells 510 may be connected in parallel on an output (i.e., high voltage) side 522 of the converters 520, as shown, for example, in FIG. 8. In some embodiments, battery energy storage system 500 may include or be connected to the monitoring devices discussed above with respect to FIG. 7. In some embodiments, battery energy storage system 500 may also include integrated thermal management, to monitor temperatures of various components of battery energy storage system 500. By implementing high-gain DC-DC converters 520 at the cell level and connecting the battery cells 510 in parallel (rather than the conventional approach of connecting the batteries in series and using a single DC-DC converter), the battery energy storage system 500 is able to maintain a stable voltage with a small loss in capacity in the event of individual cell 510 failure, which reduces field failures and maximizes the system's productive life. In contrast, failure of a single battery cell in the conventional approach may cause the DC-DC link to collapse, resulting in a compromise of the power flow and poor structural modularity.

Moreover, in the conventional approach, battery energy storage systems (particularly those using reused or repurposed cells) are carefully assembled so that they use cells that are deemed to be close in state-of-health, capacity and internal resistance, and other factors, as well as being the same make and model, chemistry, and often from the same lot to ensure safety and reliability. This careful assembly demands time and resources, thus driving up costs. The cell-level DC-DC converters 520 described herein will reduce the need for careful assembly because the criticality of each battery cell 510 is reduced through the parallel configuration. Thus, cell-level Power Electronics (cPE, such as the cell-level DC-DC converters 520) with integrated thermal management provides a more fault-tolerant, robust, smart, and scalable system 500.

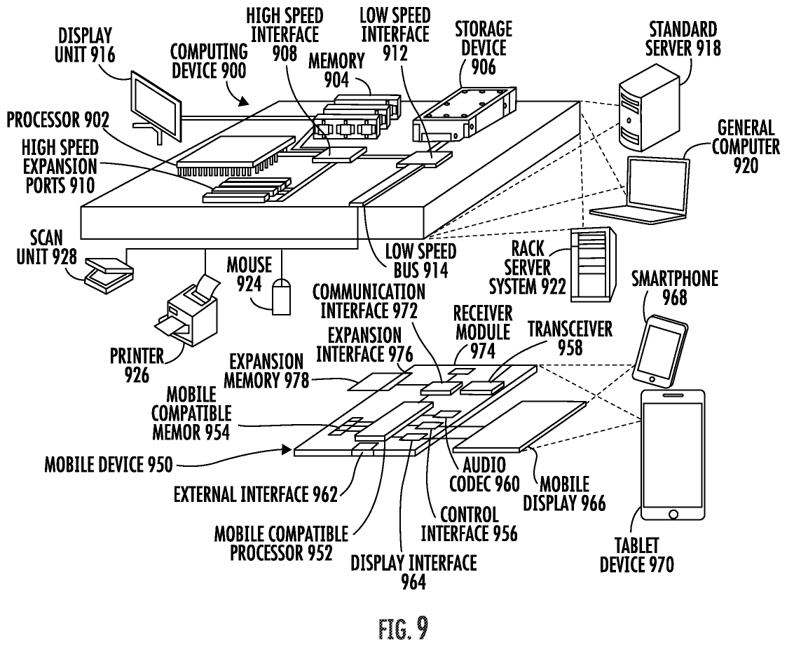

The systems and methods for processing and managing used lithium-ion batteries disclosed herein may be partially or fully implemented with a computer through software running on or associated with the computer, or an application accessible by the computer or some other electronic device. As one example, FIG. 9 is a schematic diagram of specific computing device 900 and a specific mobile computing device 950 that can be used to perform and/or implement any of the embodiments disclosed herein.

The specific computing device 900 may represent various forms of digital computers, such as laptops, desktops, workstations, personal digital assistants, servers, blade servers, mainframes, and/or other appropriate computers. The specific mobile computing device 950 may represent various forms of mobile devices, such as smartphones, camera phones, personal digital assistants, cellular telephones, and other similar mobile devices. The components shown here, their connections, couples, and relationships, and their functions, are meant to be exemplary only, and are not meant to limit the embodiments described and/or claimed, according to one embodiment.

The specific computing device 900 may include a processor 902, a memory 904, a storage device 906, a high-speed interface 908 coupled to the memory 904 and a plurality of high-speed expansion ports 910, and a low-speed interface 912 coupled to a low-speed bus 914 and a storage device 906. In one embodiment, each of the components heretofore may be inter-coupled using various buses, and may be mounted on a common motherboard and/or in other manners as appropriate. The processor 902 may process instructions for execution in the specific computing device 900, including instructions stored in the memory 904 and/or on the storage device 906 to display a graphical information for a GUI on an external input/output device, such as a display unit 916 coupled to the high-speed interface 908, according to one embodiment.

In other embodiments, multiple processors and/or multiple buses may be used, as appropriate, along with multiple memories and/or types of memory. Also, a plurality of specific computing devices 900 may be coupled together, with each device providing portions of the necessary operations (e.g., as a server bank, a group of blade servers, and/or a multi-processor system).

The memory 904 may be coupled to the specific computing device 900. In one embodiment, the memory 904 may be a volatile memory. In another embodiment, the memory 904 may be a non-volatile memory. The memory 904 may also be another form of computer-readable medium, such as a magnetic and/or an optical disk. The storage device 906 may be capable of providing mass storage for the specific computing device 900. In one embodiment, the storage device 906 may be a floppy disk device, a hard disk device, an optical disk device, a tape device, a flash memory and/or other similar solid state memory device. In another embodiment, the storage device 906 may be an array of the devices in a computer-readable medium previously mentioned heretofore, including devices in a storage area network and/or other configurations.

A computer program may be comprised of instructions that, when executed, perform one or more methods, such as those described above. The instructions may be stored in the memory 904, the storage device 906, a memory coupled to the processor 902, and/or a propagated signal.

The high-speed interface 908 may manage bandwidth-intensive operations for the specific computing device 900, while the low-speed interface 912 may manage lower bandwidth-intensive operations. Such allocation of functions is exemplary only. In one embodiment, the high-speed interface 908 may be coupled to the memory 904, the display unit 916 (e.g., through a graphics processor and/or an accelerator), and to the plurality of high-speed expansion ports 910, which may accept various expansion cards.

In one embodiment, the low-speed interface 912 may be coupled to the storage device 906 and the low-speed bus 914. The low-speed bus 914 may be comprised of a wired and/or wireless communication port (e.g., a Universal Serial Bus (“USB”), a Bluetooth® port, an Ethernet port, and/or a wireless Ethernet port). The low-speed bus 914 may also be coupled to the scan unit 928, a printer 926, a keyboard, a mouse 924, and a networking device (e.g., a switch and/or a router) through a network adapter.

The specific computing device 900 may be implemented in a number of different forms, as shown in the figure. In one embodiment, the specific computing device 900 may be implemented as a standard server 918 and/or a group of such servers. In another embodiment, the specific computing device 900 may be implemented as part of a rack server system 922. In yet another embodiment, the specific computing device 900 may be implemented as a general computer 920 such as a laptop or desktop computer. Alternatively, a component from the specific computing device 900 may be combined with another component in a specific mobile computing device 950. In one or more embodiments, an entire system may be made up of a plurality of specific computing devices 900 and/or a plurality of specific computing devices 900 coupled to a plurality of specific mobile computing devices 950.

In one embodiment, the specific mobile computing device 950 may include a mobile compatible processor 952, a mobile compatible memory 954, and an input/output device such as a mobile display 966, a communication interface 972, and a transceiver 958, among other components. The specific mobile computing device 950 may also be provided with a storage device, such as a microdrive or other device, to provide additional storage. In one embodiment, the components indicated heretofore are inter-coupled using various buses, and several of the components may be mounted on a common motherboard.

The mobile compatible processor 952 may execute instructions in the specific mobile computing device 950, including instructions stored in the mobile compatible memory 954. The mobile compatible processor 952 may be implemented as a chipset of chips that include separate and multiple analog and digital processors. The mobile compatible processor 952 may provide, for example, for coordination of the other components of the specific mobile computing device 950, such as control of user interfaces, applications run by the specific mobile computing device 950, and wireless communication by the specific mobile computing device 950.

The mobile compatible processor 952 may communicate with a user through the control interface 956 and the display interface 964 coupled to a mobile display 966. In one embodiment, the mobile display 966 may be a Thin-Film-Transistor Liquid Crystal Display (“TFT LCD”), an Organic Light Emitting Diode (“OLED”) display, or another appropriate display technology. The display interface 964 may comprise appropriate circuitry for driving the mobile display 966 to present graphical and other information to a user. The control interface 956 may receive commands from a user and convert them for submission to the mobile compatible processor 952.

In addition, an external interface 962 may be in communication with the mobile compatible processor 952, so as to enable near area communication of the specific mobile computing device 950 with other devices. External interface 962 may provide, for example, for wired communication in some embodiments, or for wireless communication in other embodiments, and multiple interfaces may also be used.

The mobile compatible memory 954 may be coupled to the specific mobile computing device 950. The mobile compatible memory 954 may be implemented as a volatile memory and a non-volatile memory. The expansion memory 978 may also be coupled to the specific mobile computing device 950 through the expansion interface 976, which may comprise, for example, a Single In Line Memory Module (“SIMM”) card interface. The expansion memory 978 may provide extra storage space for the specific mobile computing device 950, or may also store an application or other information for the specific mobile computing device 950.

Specifically, the expansion memory 978 may comprise instructions to carry out the processes described above. The expansion memory 978 may also comprise secure information. For example, the expansion memory 978 may be provided as a security module for the specific mobile computing device 950, and may be programmed with instructions that permit secure use of the specific mobile computing device 950. In addition, a secure application may be provided on the SIMM card, along with additional information, such as placing identifying information on the SIMM card in a non-hackable manner.

The mobile compatible memory may include a volatile memory (e.g., a flash memory) and a non-volatile memory (e.g., a non-volatile random-access memory (“NVRAM”)). In one embodiment, a computer program comprises a set of instructions that, when executed, perform one or more methods. The set of instructions may be stored on the mobile compatible memory 954, the expansion memory 978, a memory coupled to the mobile compatible processor 952, and a propagated signal that may be received, for example, over the transceiver 958 and/or the external interface 962.

The specific mobile computing device 950 may communicate wirelessly through the communication interface 972, which may be comprised of a digital signal processing circuitry. The communication interface 972 may provide for communications using various modes and/or protocols, such as a Global System for Mobile Communications (“GSM”) protocol, a Short Message Service (“SMS”) protocol, an Enhanced Messaging System (“EMS”) protocol, a Multimedia Messaging Service (“MIMS”) protocol, a Code Division Multiple Access (“CDMA”) protocol, Time Division Multiple Access (“TDMA”) protocol, a Personal Digital Cellular (“PDC”) protocol, a Wideband Code Division Multiple Access (“WCDMA”) protocol, a CDMA2000 protocol, and a General Packet Radio Service (“GPRS”) protocol.

Such communication may occur, for example, through the transceiver 958 (e.g., radio-frequency transceiver). In addition, short-range communication may occur, such as using a Bluetooth®, Wi-Fi, and/or other such transceiver. In addition, a GPS (“Global Positioning System”) receiver module 974 may provide additional navigation-related and location-related wireless data to the specific mobile computing device 950, which may be used as appropriate by a software application running on the specific mobile computing device 950.

The specific mobile computing device 950 may also communicate audibly using an audio codec 960, which may receive spoken information from a user and convert it to usable digital information. The audio codec 960 may likewise generate audible sound for a user, such as through a speaker (e.g., in a handset smartphone of the specific mobile computing device 950). Such a sound may comprise a sound from a voice telephone call, a recorded sound (e.g., a voice message, a music files, etc.) and may also include a sound generated by an application operating on the specific mobile computing device 950.

The specific mobile computing device 950 may be implemented in a number of different forms, as shown in the figure. In one embodiment, the specific mobile computing device 950 may be implemented as a smartphone 968. In another embodiment, the specific mobile computing device 950 may be implemented as a personal digital assistant (“PDA”). In yet another embodiment, the specific mobile computing device, 950 may be implemented as a tablet device 970.

Various embodiments of the systems and techniques described here can be realized in a digital electronic circuitry, an integrated circuitry, a specially designed application specific integrated circuits (“ASICs”), a piece of computer hardware, a firmware, a software application, and a combination thereof. These various embodiments can include embodiments in one or more computer programs that are executable and/or interpretable on a programmable system including one programmable processor, which may be special or general purpose, coupled to receive data and instructions from, and to transmit data and instructions to, a storage system, one input device, and at least one output device.

These computer programs (also known as programs, software, software applications, and/or code) comprise machine-readable instructions for a programmable processor, and can be implemented in a high-level procedural and/or object-oriented programming language, and/or in assembly/machine language. As used herein, the terms “machine-readable medium” and/or “computer-readable medium” refers to any computer program product, apparatus and/or device (e.g., magnetic discs, optical disks, memory, and/or Programmable Logic Devices (“PLDs”)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here may be implemented on a computing device having a display device (e.g., a cathode ray tube (“CRT”) and/or liquid crystal (“LCD”) monitor) for displaying information to the user and a keyboard and a mouse by which the user can provide input to the computer. Other kinds of devices can be used to provide for interaction with a user as well; for example, feedback provided to the user can be any form of sensory feedback (e.g., visual feedback, auditory feedback, and/or tactile feedback) and input from the user can be received in any form, including acoustic, speech, and/or tactile input.

The systems and techniques described here may be implemented in a computing system that includes a back end component (e.g., as a data server), a middleware component (e.g., an application server), a front end component (e.g., a client computer having a graphical user interface, and/or a Web browser through which a user can interact with an embodiment of the systems and techniques described here), and a combination thereof. The components of the system may also be coupled through a communication network.

The communication network may include a local area network (“LAN”) and a wide area network (“WAN”) (e.g., the Internet). The computing system can include a client and a server. In one embodiment, the client and the server are remote from each other and interact through the communication network.

Many additional implementations are possible. Further implementations are within the CLAIMS.

It will be understood that implementations of the systems and methods for processing and managing used lithium-ion batteries include but are not limited to the specific components disclosed herein, as virtually any components consistent with the intended operation of various systems and methods for processing and managing used lithium-ion batteries may be utilized. Accordingly, for example, it should be understood that, while the drawings and accompanying text show and describe particular implementations of systems and methods for processing and managing used lithium-ion batteries, any such implementation may comprise any shape, size, style, type, model, version, class, grade, measurement, concentration, material, weight, quantity, and/or the like consistent with the intended operation of systems and methods for processing and managing used lithium-ion batteries.

The concepts disclosed herein are not limited to the specific systems and methods for processing and managing used lithium-ion batteries shown herein. For example, it is specifically contemplated that the components included in particular systems and methods for processing and managing used lithium-ion batteries may be formed of any of many different types of materials or combinations that can readily be formed into shaped objects and that are consistent with the intended operation of the systems and methods for processing and managing used lithium-ion batteries. For example, the components may be formed of: rubbers (synthetic and/or natural) and/or other like materials; glasses (such as fiberglass), carbon-fiber, aramid-fiber, any combination therefore, and/or other like materials; elastomers and/or other like materials; polymers such as thermoplastics (such as ABS, fluoropolymers, polyacetal, polyamide, polycarbonate, polyethylene, polysulfone, and/or the like, thermosets (such as epoxy, phenolic resin, polyimide, polyurethane, and/or the like), and/or other like materials; plastics and/or other like materials; composites and/or other like materials; metals, such as zinc, magnesium, titanium, copper, iron, steel, carbon steel, alloy steel, tool steel, stainless steel, spring steel, aluminum, and/or other like materials; and/or any combination of the foregoing.

Furthermore, systems for processing and managing used lithium-ion batteries may be manufactured separately and then assembled together, or any or all of the components may be manufactured simultaneously and integrally joined with one another. Manufacture of these components separately or simultaneously, as understood by those of ordinary skill in the art, may involve 3-D printing, extrusion, pultrusion, vacuum forming, injection molding, blow molding, resin transfer molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled or removably coupled with one another in any manner, such as with adhesive, a weld, a fastener, any combination thereof, and/or the like for example, depending on, among other considerations, the particular material(s) forming the components.

In places where the description above refers to particular implementations of systems and methods for processing and managing used lithium-ion batteries, it should be readily apparent that a number of modifications may be made without departing from the spirit thereof and that these implementations may be applied to other implementations disclosed or undisclosed. The presently disclosed systems and methods for processing and managing used lithium-ion batteries are, therefore, to be considered in all respects as illustrative and not restrictive.

I/We claim:

1. A method for processing used lithium-ion batteries, the method comprising:
disassembling a used lithium-ion battery, wherein the used lithium-ion battery is configured for a high-load application;
inspecting cells of the used lithium-ion battery;
charging the cells of the used lithium-ion battery;
assessing a state-of-health of each of the cells by:
running a discharge test to determine an internal resistance and a capacity of each of the cells;
comparing the internal resistance and the capacity with manufacturer specifications for each of the cells; and
determining the state-of-health based on the comparison;
categorizing each of the cells into one of a plurality of categories comprising a reuse category, a repurpose category, and a recycle category based on the state-of-health of each of the cells; and
reusing the cells categorized in the reuse category in a battery configured for a high-load application, repurposing the cells categorized in the repurpose category into a battery configured for a low-load application, and recycling the cells categorized in the recycle category.

2. The method of claim 1, further comprising analyzing the battery configured for a high-load application comprising the cells categorized in the reuse category and the battery configured for a low-load application comprising the cells categorized in the repurpose category while in use to determine performance metrics.

3. The method of claim 2, further comprising:
storing the performance metrics of the battery configured for a high-load application comprising the cells categorized in the reuse category and the battery configured for a low-load application comprising the cells categorized in the repurpose category in a database; and
performing statistical analysis based on the stored performance metrics to identify state-of-health drivers.

4. The method of claim 3, further comprising using the statistical analysis to improve future state-of-health determinations of cells of used lithium-ion batteries.

5. The method of claim 1, wherein the battery configured for a high-load application comprising the cells categorized in the reuse category comprises a combination of new cells and the cells categorized in the reuse category.

6. The method of claim 1, wherein assessing the state-of-health of each of the cells further comprises determining a temperature rise during the discharge test and comparing the temperature rise with a threshold.

7. The method of claim 1, wherein the state-of-health comprises a grade.

8. The method of claim 1, wherein the state-of-health comprises an estimate of life remaining for the cell.

9. A method for processing used lithium-ion batteries, the method comprising:
disassembling a used lithium-ion battery;
analyzing cells of the used lithium-ion battery during a discharge test;
assigning grades to a plurality of factors for each of the analyzed cells based on the discharge test;
determining a state-of-health for each of the analyzed cells based on the grades of each of the plurality of factors;
categorizing each of the analyzed cells into one of a plurality of categories comprising a reuse category, a repurpose category, and a recycle category based on the state-of-health of each of the analyzed cells; and
reusing the cells categorized in the reuse category in a battery configured for a high-load application, repurposing the cells categorized in the repurpose category into a battery configured for a low-load application, and recycling the cells categorized in the recycle category.

10. The method of claim 9, wherein the plurality of factors comprises an internal resistance, a capacity, and a temperature rise.

11. The method of claim 9, wherein a grade of at least one of the plurality of factors is based on a comparison with manufacturer specifications for each of the analyzed cells.

12. The method of claim 9, further comprising charging cells of the used lithium-ion battery; and evaluating a charge of each of the charged cells during a waiting period.

13. The method of claim 12, wherein the charged cells are only analyzed if the charge exceeds a predetermined voltage throughout the waiting period.

14. The method of claim 12, wherein the waiting period comprises at least one day.

15. A method for processing used lithium-ion batteries, the method comprising:
individually assessing a state-of-health of cells of a used lithium-ion battery configured for a high-load application;
categorizing each of the cells into one of a plurality of categories comprising a reuse category, a repurpose category, and a recycle category based on the state-of-health of each of the cells; and
repurposing the cells categorized in the repurpose category into a battery configured for a low-load application.

16. The method of claim 15, further comprising reusing the cells categorized in the reuse category in a battery configured for a high-load application and recycling the cells categorized in the recycle category.

17. The method of claim 15, wherein the state-of-health of each of the cells is based on a plurality of factors, the plurality of factors comprising an internal resistance of each of the cells and a capacity of each of the cells.

18. The method of claim 15, wherein the battery configured for a low-load application comprises a combination of new cells and cells categorized in the repurpose category.

19. The method of claim 15, wherein individually assessing the state-of-health of the cells comprises running a discharge test on each of the cells to determine a capacity and an internal resistance of each of the cells.

20. The method of claim 19, wherein individually assessing the state-of-health of the cells comprises, for each of the cells:
comparing the capacity and the internal resistance of the cell with manufacturer specifications for the cell.
